(19) United States
(12) Patent Application Publication
(10) Pub. No.: US 2015/0279472 A1
(43) Pub. Date: Oct. 1, 2015

(54) TEMPERATURE COMPENSATION VIA MODULATION OF BIT LINE VOLTAGE DURING SENSING

(71) Applicant: Intel Corporation, Santa Clara, CA (US)

(72) Inventor: Mason Jones, Boise, ID (US)

(73) Assignee: Intel Corporation, Santa Clara, CA (US)

(21) Appl. No.: 14/226,354

(22) Filed: Mar. 26, 2014

(51) Int. Cl. G11C 16/24; G11C 16/34; G11C 16/26

(52) U.S. Cl. CPC G11C 16/24; G11C 16/26; G11C 16/3459

(57) ABSTRACT

Embodiments of systems and methods described herein relate to temperature compensation of the sense conditions of memory cells during cross temperatures read operations. One embodiment provides a memory device comprising one or more memory cells, a temperature sensor and a controller coupled to the temperature sensor. The temperature sensor measures a temperature of at least one memory cell. The controller modulates a bit line voltage of the at least one memory cell during a program verify or read operation if the read temperature of the at least one memory cell is different from a first temperature of the memory cell.

### TECHNICAL FIELD

Embodiments of systems and techniques described herein relate to memory systems. More particularly, embodiments of systems and techniques described herein relate to temperature compensation of the sense conditions of memory cells during cross temperatures read operations.

### BACKGROUND

A vertical NAND string device comprises a thin channel that has been formed along a pillar. Various devices, such as a select gate source (SGS), one or more non-volatile memory cells (NAND memory cells), one or more control gates and a select gate drain (SGD) are arranged along the thin channel. The channel is connected at one end to a bit line (BL) and at the other end to a source. A first select signal is applied to the SGD to control conduction through the channel at the BL end of the channel, and a second signal is applied to the SGS to control conduction through the channel at the source end of the channel. The vertical NAND string device can be arranged into a memory array in which the NAND memory cells are located at intersections of column signal lines (e.g., bit lines) and row signal lines (e.g., word lines). Individual column and/or row signal lines are electrically connected to a memory controller (not shown) to selectively access and operate the NAND memory cells.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts a functional block diagram of an exemplary embodiment of a memory device that provides temperature compensation by modulating a bit line voltage during a sense (read) operation according to the subject matter disclosed herein;

FIGS. 2A-2C depict one exemplary embodiment of a NAND string device according to the subject matter disclosed herein;

FIG. 3 depicts a graph showing the distribution of Vt for a full page read at selected operating temperatures for a conventional technique of increasing the voltage applied to the unselected word lines (VPASS/VWLRV) as the operating temperature drops of the memory cells below the temperature at which the memory cells were programmed;

FIG. 4 depicts a graph showing the distribution of Vt for a full page read at selected operating temperatures for a temperature compensation technique according to the subject matter disclosed herein;

FIG. 5 depicts a flow diagram of an exemplary embodiment of a process for providing temperature compensation by modulating a bit line voltage during a sense (read) operation according to the subject matter disclosed herein;

FIG. 6 depicts a schematic diagram of an exemplary embodiment of a memory array comprising one or more temperature sensors for sensing the temperature of one or more memory cells for providing temperature compensation for cross-temperature read operations according to the subject matter disclosed herein; and

FIG. 7 depicts a functional block diagram of an exemplary embodiment of an electronic system comprising a memory array comprising one or more temperature sensors for sensing the temperature of one or more memory cells for providing temperature compensation for cross-temperature read operations according to the subject matter disclosed herein.

It will be appreciated that for simplicity and/or clarity of illustration, elements depicted in the figures have not necessarily been drawn to scale. For example, the dimensions of some of the elements may be exaggerated relative to other elements for clarity. The scaling of the figures does not represent precise dimensions and/or dimensional ratios of the various elements depicted herein. Further, if considered appropriate, reference numerals have been repeated among the figures to indicate corresponding and/or analogous elements.

### DESCRIPTION OF THE EMBODIMENTS

Embodiments described herein relate to systems and techniques that provide temperature compensation of the sense conditions during cross temperatures read operations. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. Additionally, the word “exemplary” is used herein to mean “serving as an example, instance, or illustration.” Any embodiment described herein as “exemplary” is not to be construed as necessarily preferred or advantageous over other embodiments.

Various operations may be described as multiple discrete operations in turn and in a manner that is most helpful in understanding the claimed subject matter. The order of description, however, should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

As the operating temperature of a NAND-type memory device changes, the distribution of the threshold voltages Vt of the memory cells changes. If the memory cells of an NAND-type memory device are programmed at a relatively high operating temperature, the distribution of Vt of the memory cells is relatively narrow at the relatively high operating temperature. If, however, the operating temperature of the NAND-type memory device drops from the temperature at which the memory cells were programmed, the distribution of Vt of the memory cells programmed at the relatively higher operating temperature becomes significantly wider, thus making unreliable the reading at the lower operating temperature of the memory cells programmed at the relatively higher temperature. A conventional technique that has been used to compensate for the change in distribution of Vt of memory cells involves increasing the voltage applied to unselected word lines of the NAND-type memory device (referred to herein as VPASS/VWLRV) as the operating temperature drops below the temperature at which the memory cells were programmed. Such a conventional technique, however, increases the likelihood of read disturb for the NAND-type memory device.

The subject matter disclosed herein provides a temperature compensation technique that modulates a bit line voltage during a sense (read) operation for cross-temperature read operations without increasing the probability of read disturb. In one exemplary embodiment, the subject matter disclosed herein provides a temperature compensation technique in which the voltage of each selected bit line is modulated during a read operation by increasing the bit line voltage for a selected memory cell that is at an operating temperature that is lower temperature than the operating temperature at which the memory cell was programmed, thereby providing a more accurate read operation and without increasing the likelihood of read disturb.

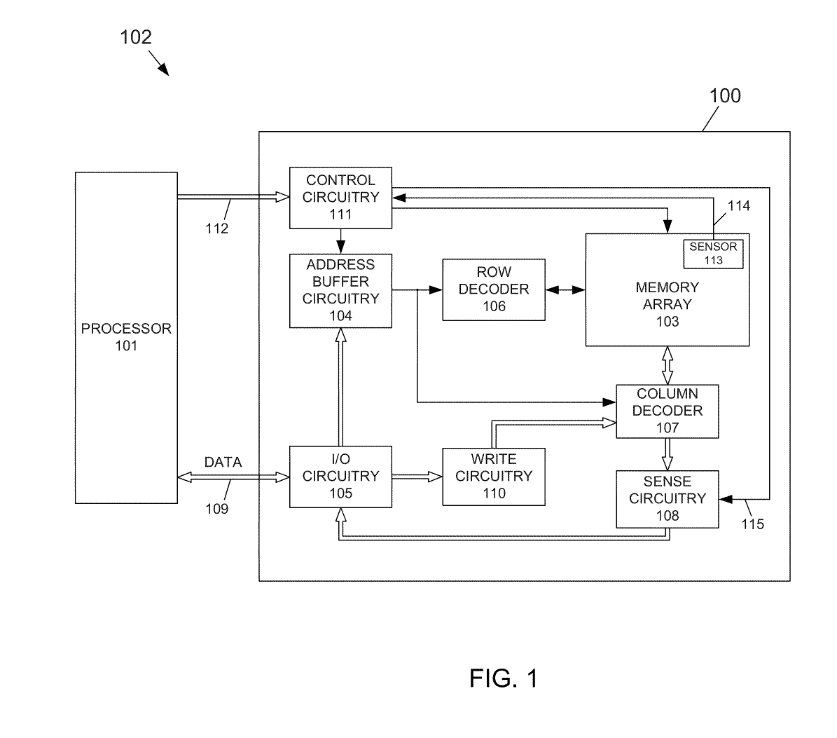

FIG. 1 depicts a functional block diagram of an exemplary embodiment of a memory device 100 that provides temperature compensation by modulating a bit line voltage during a sense (read) operation according to the subject matter disclosed herein. Memory device 100 is depicted as being coupled to an external processor 101. Processor 101 may be a microprocessor or some other type of controller. Memory device 100 and processor 101 form part of a memory system 102. It should be understood that memory device 100 is depicted in a simplified manner to focus on features of memory device 100 that are helpful for understanding the subject matter disclosed herein.

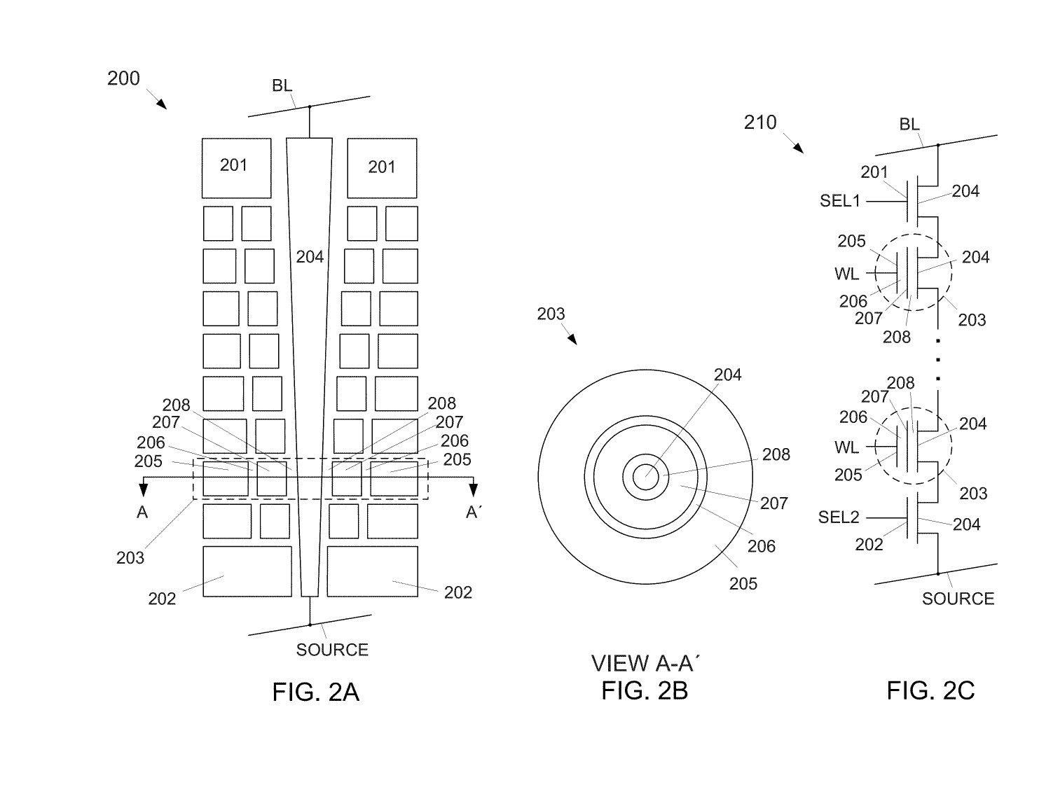

Memory device 100 comprises a memory array 103, an address buffer circuitry 104, I/O circuitry 105, a row decoder 106, a column decoder 107, sense amplifier circuitry 108, write circuitry 110, and a memory control circuitry 111. Memory array 103 comprises one or more memory cells, such as, but not limited to, floating-gate memory cells. In one exemplary embodiment, memory array 103 comprises one or more vertical NAND string devices in which each NAND string device comprises one or more floating-gate memory cells. Memory array 103 is arranged in banks of word line rows and bit line columns. In one exemplary embodiment, the columns of the memory array 103 comprise series NAND string devices of memory cells. FIGS. 2A-2C depict one exemplary embodiment of a NAND string device 200 according to the subject matter disclosed herein.

Address buffer circuitry 104 latches in a well-known manner address signals that are provided through I/O circuitry 105 from processor 101. The address signals are decoded in a well-known manner by a row decoder 106 and a column decoder 107 to access memory array 103. It should be understood that the number of address input connections depends on the density and architecture of the memory array 103. That is, the number of addresses increases as both the memory cell count increases and the bank and block count increases.

Memory device 100 reads (senses) data in memory array 103 in a well-known manner by sense amplifier 108 sensing voltage or current changes in the columns of memory array 103. Sense amplifier circuitry 108, in one exemplary embodiment, is coupled to read and latch a row of data from memory array 103. I/O circuitry 105 includes data I/O buffer circuitry for buffering one or more data connections 109 to provide bi-directional data communication with processor 101. Additionally, I/O circuitry 105 includes buffer circuitry for buffering address communications. Write circuitry 110 writes data in a well-known manner to memory array 103.

Memory control circuitry 111 decodes control signals 112 received from processor 101. Control signals 112 are used to control the operations of memory system 102 including data read, data write (program), and erase operations. Memory control circuitry 111 may be a state machine, a sequencer, or some other type of controller to generate the memory control signals. In one exemplary embodiment, memory control circuitry 111 is configured to control the timing and generation of voltages writing data to and reading data from memory array 103.

Memory device 100 includes one or more temperature sensors located around the die forming memory device 100. In one exemplary embodiment, one or more temperature sensors 113 are distributed around memory array 103 to sense the operating temperature of memory array 103. In one exemplary embodiment, there may be a temperature sensor for each memory cell of the memory device. In another exemplary embodiment, the number of temperature sensors are selected and distributed around the memory array of the memory device to provide a sufficiently accurate temperature measurement of each memory cell of the memory device. It should be understood that although only a single temperature sensor 113 is depicted in FIG. 1 for clarity, additional temperatures sensors could be used. Each temperature sensor 113 outputs a sensor signal 114 to control circuitry 111. In response to sensor signal(s) 114, control circuitry 111 outputs one or more control signals 115 that respectively control the voltage level of each bit line that is being sensed during a read operation. That is, according to the subject matter disclosed herein that, control circuitry 111 modulates the voltage of each selected bit line during a read operation by increasing the bit line voltage for a selected memory cell that is at an operating temperature that is lower temperature than the operating temperature at which the memory cell was programmed, thereby providing a more accurate read operation and without increasing the likelihood of read disturb.

FIG. 2A depicts a side cross-sectional view of a one exemplary embodiment of a vertical NAND string 200. Vertical NAND string 200 comprises a select gate drain (SGD) 201, a select gate source (SGS) 202, one or more individual flash cells 203 (of which only one flash cell is indicated in FIG. 2A), and a channel 204. FIG. 2B depicts a cross-sectional view of an individual NAND cell 203 as viewed at line A-A′ in FIG. 2A. FIG. 2C depicts a schematic diagram 210 of vertical NAND string 200 in which only two individual NAND cells 203 are depicted.

NAND cells 203 are non-volatile memory cells that have been formed along the length of channel 204. Each individual NAND cell 203 comprises a control gate 205, a blocking dielectric 206 (also referred to as an interpoly dielectric), a charge storage node 207 (which can be a floating gate (FG) or a localized charge storage layer, such as silicon nitride in the case of CTF) (also referred to as a storage node), a tunneling dielectric 208, and a channel 204. The control gate 205 of each NAND cell 203 is coupled to a corresponding word line (WL) (not shown in FIGS. 2A and 2B). In some embodiments of vertical NAND string 200, some of NAND cells 203 toward the SGD end of channel 204 comprise “dummy” NAND cells that may or may not store data, and some NAND cells 203 toward the SGS end of channel 204 comprise NAND cells that store data (data cells).

Channel 204 is connected at one end to a bit line (BL) and at the other end to a source. A SEL1 signal applied to SGD 201 controls conduction through channel 204 at the BL end of channel 204, and a SEL2 signal applied to SGS 202 controls conduction through channel 204 at the source end of channel 204. Although FIG. 2B depicts channel 204 as comprising a generally round cross-sectional area, it should be understood that channel 204 could have a wide range of cross-sectional areas that provide a functionality that is similar to a generally round cross-sectional area.

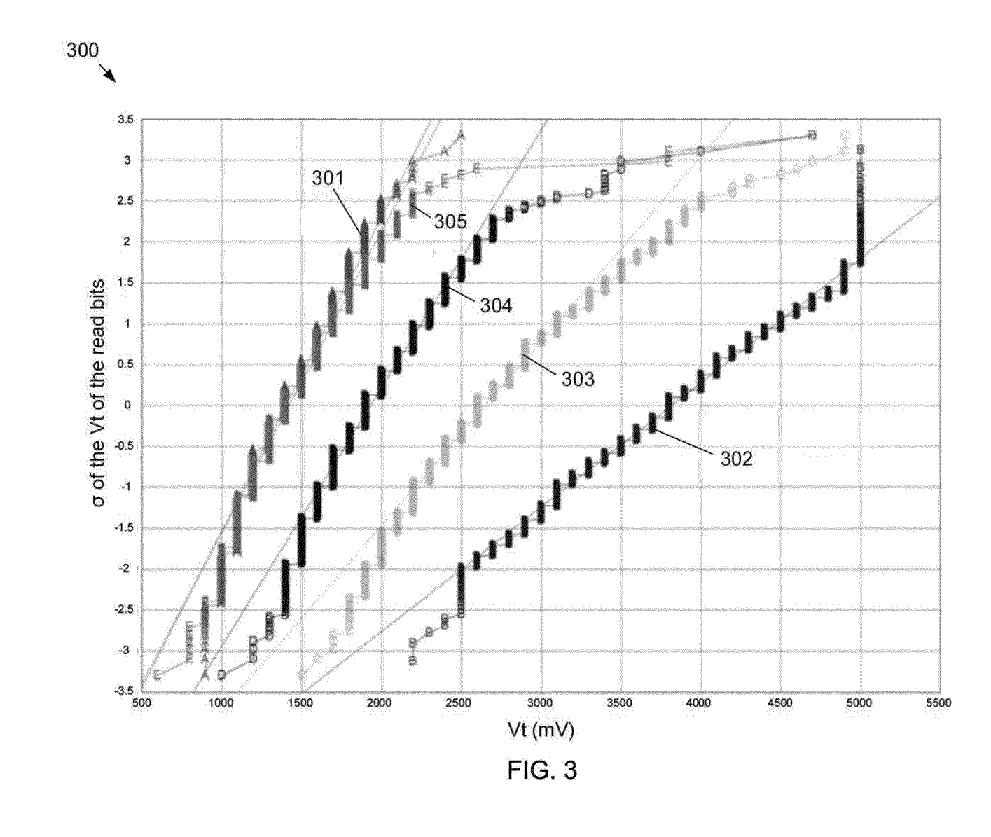

FIG. 3 depicts a graph 300 showing the distribution of Vt for a full page read at selected operating temperatures for a conventional technique of increasing the voltage applied to the unselected word lines (VPASS/VWLRV) as the operating temperature drops of the memory cells below the temperature at which the memory cells were programmed. The abscissa of graph 300 is Vt in millivolts (mV), and the ordinate of graph 300 is the sigma (σ) of the Vt of the read bits. The memory cells of the page were programmed at an operating temperature of 90 C.

Curve 301 shows the distribution of Vt of the read bits at 90 C for a voltage of 7.5 V being applied to the unselected word lines. Curve 302 shows the distribution of Vt of the read bits at 25 C for a voltage of 7.5 V being applied to the unselected word lines. That is, curve 302 shows the same operating conditions as curve 301, but at an operating temperature of 25 C. Curve 303 shows the distribution of Vt of the read bits at 25 C for a voltage of 8.0 V applied to the unselected word lines. Curve 304 shows the distribution of Vt of the read bits at 25 C for a voltage of 8.5 V applied to the unselected word lines. Curve 305 shows the distribution of Vt of the read bits at 25 C for a voltage of 9.0V applied to the unselected word lines. Thus, graph 300 shows that for a program temperature of 90 C and an operating temperature of 25 C, the conventional technique of temperature compensation increases the voltage applied to the unselected word lines from 7.5 V to 9.0V. While this approach compensates for the change in sense conditions, as the voltage applied to the unselected word lines increases, the probability of read disturb also increases.

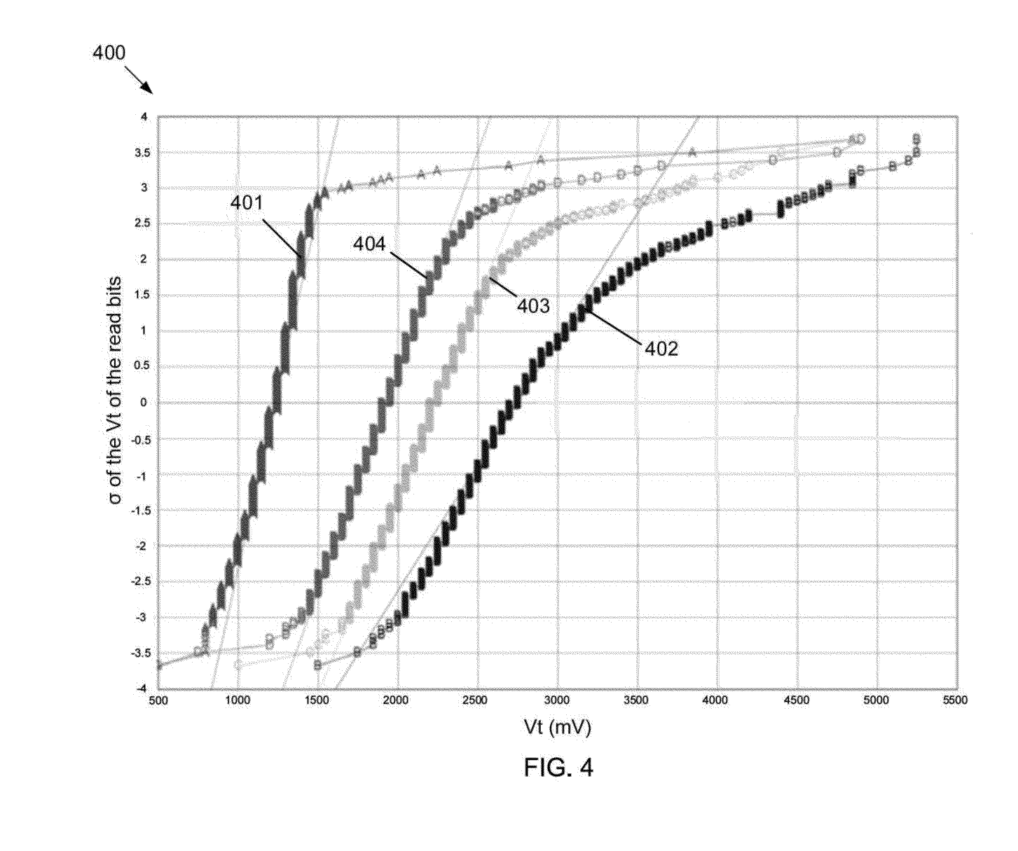

FIG. 4 depicts a graph 400 showing the distribution of Vt for a full page read at selected operating temperatures for a temperature compensation technique according to the subject matter disclosed herein. In particular, according to the subject matter disclosed herein, the bit line voltage is increased (modulated) during sensing when program verifying or reading at an operating temperature that is lower than the operating temperature at which memory cell was programmed, thereby providing a more accurate read operation. The abscissa of graph 400 is Vt in millivolts (mV), and the ordinate of graph 300 is the sigma (σ) of the Vt of the read bits. The memory cells of the page were programmed at an operating temperature of 90 C.

Curve 401 shows the distribution of Vt of the read bits at 90 C for a drain voltage (bit line voltage) having an initial clamp voltage of about 400 mV and a final clamp voltage of about 300 mV, and for a source voltage at 0 V. Curve 402 shows the distribution of Vt of the read bits at 25 C for a drain voltage (bit line voltage) having an initial clamp voltage of about 400 mV and a final clamp voltage of about 300 mV, and for a source voltage at 0 V. That is, curve 402 shows the same operating conditions as curve 401, but at an operating temperature of 25 C.

Curve 403 shows the distribution of Vt of the read bits at 25 C for a drain voltage (bit line voltage) having an initial clamp voltage of about 500 mV and a final clamp voltage of about 400 mV, and for a source voltage at 0 V. Curve 404 shows the distribution of Vt of the read bits at 25 C for a drain voltage (bit line voltage) having an initial clamp voltage of about 600 mV and a final clamp voltage of about 500 mV, and for a source voltage at 0 V. Thus, graph 400 shows that for a program temperature of 90 C and an operating temperature of 25 C, modulating the bit line voltage from an initial clamp voltage of about 400 mV and a final clamp voltage of about 300 mV to an initial clamp voltage of about 600 mV and a final clamp voltage of about 500 mV provides a temperature compensation and also provides the benefit of not increasing read stress. That is, modulating the bit line voltage increases the cell current with respect to the high temperature condition, thereby compensating for the change in the Vt that occurs over the operating temperature of memory device 100. Additionally, the likelihood of read disturb is reduced.

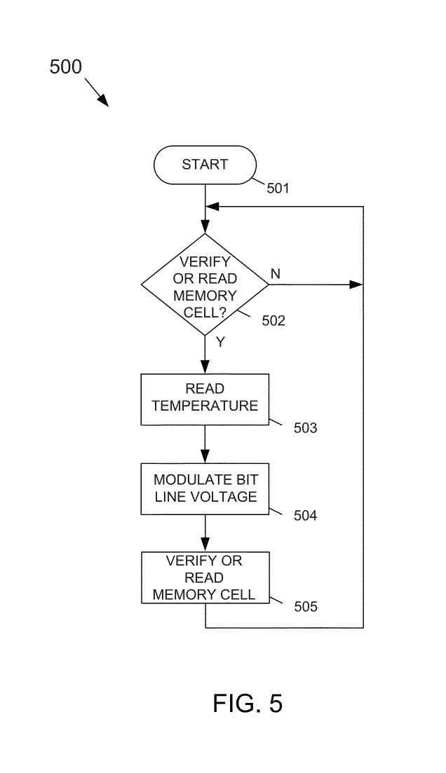

FIG. 5 depicts a flow diagram of an exemplary embodiment of a process 500 for providing temperature compensation by modulating a bit line voltage during a sense (read) operation according to the subject matter disclosed herein. At 501, the process begins. At 502, it is determined whether a memory cell of a memory device is to be program verified or read. If, at 502, the memory cell is to be program verified or read, flow continues to 503 where the temperature of the cell is determined, otherwise flow returns to 502. In one exemplary embodiment, there may be a temperature sensor for each memory cell of the memory device. In another exemplary embodiment, the number of temperature sensors are selected and distributed around the memory array of the memory device to provide a sufficiently accurate temperature measurement for each memory cell of the memory device. Flow continues from 503 to 504 where the voltage on the bit line associated with the memory cell that is to be read is modulated to provide temperature compensation based on the temperature read at the operation of 503. In one exemplary embodiment, the voltage on the bit line associated with the memory cell is modulated based on a linear relationship between two temperatures, for example, between 25 C and 90 C. If the temperature of the memory cell is measured to be substantially at 25 C, then the modulation voltage is selected to be a first modulation level, whereas if the temperature of the memory cell is measured to be substantially at 90 C, then the modulation voltage is selected to be zero (i.e., zero modulation). If the temperature of the memory cell is measured to be between 25 C and 90 C, then the modulation voltage is selected to be a linear interpolation between the first modulation level and zero. In another exemplary embodiment, if the temperature of the memory cell is measured to be between 25 C and 90 C, then the modulation voltage is selected to be one of one or more discrete modulation levels. Flow returns to 502. The particular initial and final clamp voltages (i.e., the modulation levels) will vary depending on the current operating temperature of the memory cell and the physics of the memory device.

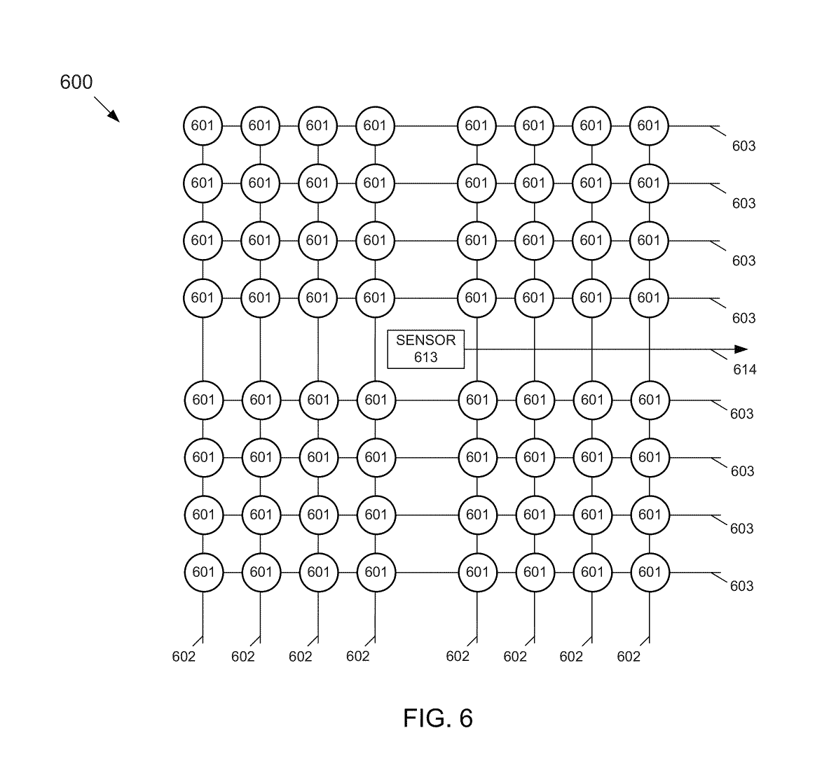

FIG. 6 depicts a schematic diagram of an exemplary embodiment of a memory array 600 comprising one or more temperature sensors for sensing the temperature of one or more memory cells for providing temperature compensation for cross-temperature read operations according to the subject matter disclosed herein. In one exemplary embodiment, at least one memory cell 601 comprises vertical NAND string device, such as depicted in FIGS. 2A-2C. As depicted in FIG. 6, memory cells 601 are located at intersections of column signal lines 602 (e.g., bit lines) and row signal lines 603 (e.g., word lines). Individual column and/or row signal lines are electrically connected in a well-known manner to a memory controller (not shown) to selectively operate memory cells 601 in a well-known manner. It should be understood that memory array 600 can comprise part of a solid-state memory array or a solid-state drive that is coupled in a well-known manner to a computer system or an information-processing system (not shown). One or more temperature sensors 613, of which only one is depicted in FIG. 6, senses the temperature of one or more memory cells 601 when a cell is programmed and when a cell is read. In one exemplary embodiment, there may be a temperature sensor for each memory cell of the memory device. In another exemplary embodiment, the number of temperature sensors are selected and distributed around the memory array of the memory device to provide a sufficiently accurate temperature measurement of each memory cell of the memory device. For example, temperature sensor 613 in FIG. 6 is positioned to provide a sufficiently accurate temperature measurement for memory cells 601. Each temperature sensor outputs a sensor signal 614 to a control circuitry, such as control circuitry 111 depicted in FIG. 1. In response to sensor signal(s) 614, the control circuitry outputs one or more control signals (not shown in FIG. 6) that respectively control the voltage level of each bit line 602 that is being sensed during a read operation. That is, according to the subject matter disclosed herein that, the control circuitry modulates the voltage of each selected bit line 602 during a read operation by increasing the bit line voltage during a read operation at an operating temperature that is lower temperature than the operating temperature at which memory cell was programmed, thereby providing a more accurate read operation.

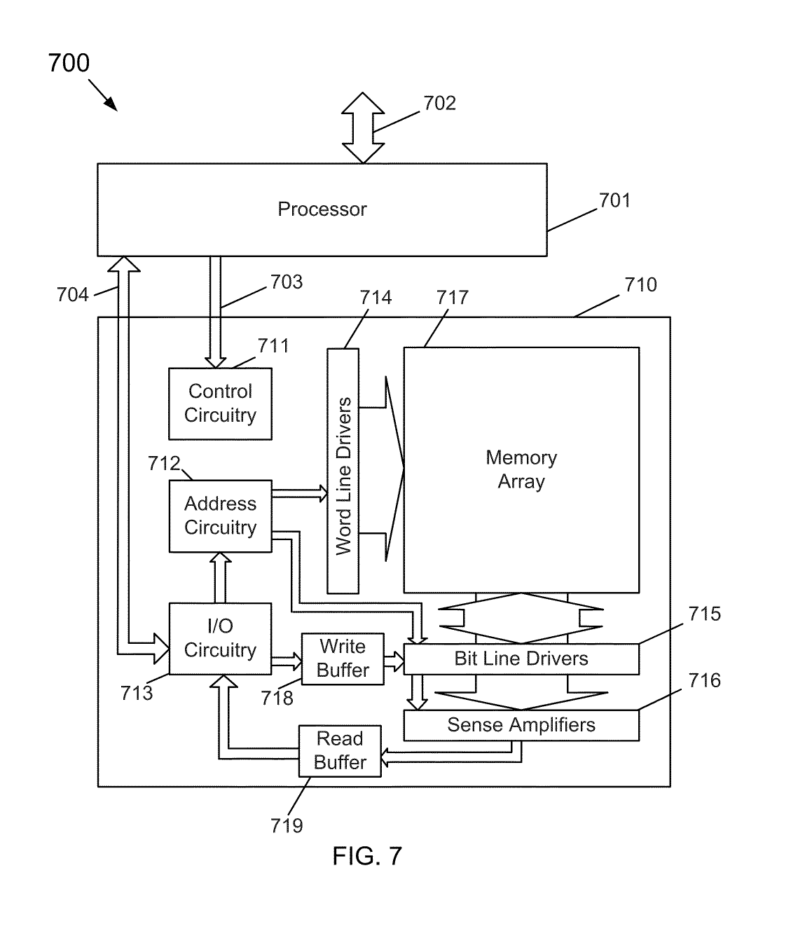

FIG. 7 depicts a functional block diagram of an exemplary embodiment of an electronic system 700 comprising a memory array comprising one or more temperature sensors for sensing the temperature of one or more memory cells for providing temperature compensation for cross-temperature read operations according to the subject matter disclosed herein. System 700 comprises a processor 701 that is coupled to a memory device 710 through control/address lines 703 and data lines 704. In some exemplary embodiments, data and control may utilize the same physical lines. In some exemplary embodiments, processor 701 may be an external microprocessor, microcontroller, or some other type of external controlling circuitry. In other exemplary embodiments, processor 701 may be integrated in the same package or even on the same die as memory device 710. In some exemplary embodiments, processor 701 may be integrated with the control circuitry 711, thereby allowing some of the same circuitry to be used for both functions. Processor 701 may have external memory, such as random access memory (RAM) (not shown) and/or read only memory (ROM) (not shown), that is used for program storage and intermediate data. Alternatively, processor 701 may have internal RAM or ROM. In some exemplary embodiments, processor 701 may use memory device 710 for program or data storage. A program running on processor 701 may implement many different functions including, but not limited to, an operating system, a file system, defective chunk remapping, and error management.

In some exemplary embodiments, an external connection 702 is provided that allows processor 701 to communicate to external devices (not shown). Additional I/O circuitry (not shown) may be used to couple external connection 702 to processor 701. If electronic system 700 is a storage system, external connection 702 may be used to provide an external device with non-volatile storage. In one exemplary embodiment, electronic system 700 may be, but is not limited to, a solid-state drive (SSD), a USB thumb drive, a secure digital card (SD Card), or any other type of storage system. External connection 702 may be used to connect to a computer or other intelligent device, such as a cell phone or digital camera, using a standard or proprietary communication protocol. Exemplary computer communication protocols that may be compatible with external connection 702 include, but are not limited to, any version of the following protocols: Universal Serial Bus (USB), Serial Advanced Technology Attachment (SATA), Small Computer System Interconnect (SCSI), Fibre Channel, Parallel Advanced Technology Attachment (PATA), Integrated Drive Electronics (IDE), Ethernet, IEEE-1394, Secure Digital Card interface (SD Card), Compact Flash interface, Memory Stick interface, Peripheral Component Interconnect (PCI) or PCI Express.

If electronic system 700 is a computing system, such as a mobile telephone, a tablet, a notebook computer, a set-top box, or some other type of computing system, external connection 702 may be a network connection such as, but not limited to, any version of the following protocols: Institute of Electrical and Electronic Engineers (IEEE) 802.3, IEEE 802.11, Data Over Cable Service Interface Specification (DOCSIS), digital television standards such as Digital Video Broadcasting (DVB)-Terrestrial, DVB-Cable, and Advanced Television Committee Standard (ATSC), and mobile telephone communication protocols such as Global System for Mobile Communication (GSM), protocols based on code division multiple access (CDMA) such as CDMA2000, and Long Term Evolution (LTE).

Memory device 710 may include an array 717 of memory cells. Memory cell array 717 may be organized as a two dimensional or a three dimensional cross-point array and may include a phase-change memory (PCM), a phase-change memory with switch (PCMS), a resistive memory, nanowire memory, ferro-electric transistor random access memory (FeTRAM), a flash memory, magnetoresistive random access memory (MRAM) memory that incorporates memristor technology, a spin transfer torque (STT)-MRAM, or any other type of memory constructed as a cross-point array. In one exemplary embodiment, memory cell array 717 comprises one or more DHC vertical NAND string devices comprising at least two three-dimensional (3D) thin channel regions formed on top of each other within the same pillar structure according to the subject matter disclosed herein. Memory array 717 may be coupled to the word line drivers 714 and/or bit line drivers 715, and/or sense amplifiers 716 in a well-known manner. Address lines and control lines 703 may be received and decoded by control circuitry 711, I/O circuitry 713 and address circuitry 712, which may provide control to the memory array 717. I/O circuitry 713 may couple to data lines 704 thereby allowing data to be received from and sent to processor 701. Data read from memory array 717 may be temporarily stored in read buffers 719. Data to be written to memory array 717 may be temporarily stored in write buffers 718 before being transferred to the memory array 717.

It should be understood that electronic system 700 depicted in FIG. 7 has been simplified to facilitate a basic understanding of the features of the system. Many different embodiments are possible including using a single processor 701 to control one or more memory devices 710 to provide for more storage space. Additional functions, such as a video graphics controller driving a display, and other devices for human-oriented I/O may be included in some exemplary embodiments.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

1. A memory device, comprising:
one or more memory cells;
at least one temperature sensor to measure a temperature of at least one memory cell; and
a controller coupled to the at least one temperature sensor to modulate a bit line voltage of the at least one memory cell during a program verify or a read operation if a read temperature of the at least one memory cell is different from a first temperature of the memory cell.

2. The memory device according to claim 1, wherein the controller modulates the bit line voltage of the at least one memory cell during the program verify or the read operation by using an initial clamp voltage that is different from an initial clamp voltage that is used to program verify or read the at least one memory cell at the first temperature and by using a final clamp voltage that is different from a final clamp voltage that is used to program verify or read the at least one memory cell at the first temperature.

3. The memory device according to claim 2, wherein initial clamp voltage used during the program verify or read operation is about 200 mV different from the initial clamp voltage used to program verify or read the at least one memory cell at the first temperature and the final clamp voltage is about 200 mV different from the final clamp voltage used to program verify or read the at least one memory cell at the first temperature.

4. The memory device according to claim 1, wherein the one or more memory cells comprises one or more NAND-type string devices.

5. The memory device according to claim 1, wherein the one or more memory cells comprises one or more non-volatile memory cells.

6. The memory device according to claim 1, wherein the memory device comprises part of a solid-state drive (SSD).

7. The memory device according to claim 1, wherein the memory device comprises part of an array of memory devices.

8. A memory device, comprising:
one or more non-volatile memory cells arranged in rows and columns, each row of memory cells being coupled to a word line and each column of memory cells being coupled to a bit line;
at least one temperature sensor to measure a temperature of at least one memory cell; and
a controller coupled to the at least one temperature sensor to modulate a bit line voltage of the at least one memory cell during a program verify or a read operation if the read temperature of the at least one memory cell is different from a first temperature of the memory cell by a predetermined amount.

9. The memory device according to claim 8, wherein the controller modulates the bit line voltage of the at least one memory cell during the program verify or read operation by using an initial clamp voltage that is different from an initial clamp voltage that is used to program verity or read the at least one memory cell at the first temperature and by using a final clamp voltage that is different from a final clamp voltage that is used to program verify or read the at least one memory cell at the first temperature.

10. The memory device according to claim 9, wherein initial clamp voltage used during the program verify or read operation is about 200 mV different from the initial clamp voltage used to program verify or read the at least one memory cell at the first temperature and the final clamp voltage is about 200 mV different from the final clamp voltage is to program verify or read the at least one memory cell.

11. The memory device according to claim 8, wherein the one or more memory cells comprises one or more NAND-type string devices.

12. The memory device according to claim 8, wherein the memory device comprises part of a solid-state drive (SSD).

13. The memory device according to claim 8, wherein the memory device comprises part of an array of memory devices.

14. A method to temperature compensate a read operation of a memory device, the method comprising:
determining a temperature of the at least one memory cell if the at least one memory cell is to be program verified or read; and
modulating a bit line voltage coupled to the at least one memory cell if the program verify or read temperature of the at least one memory cell is different from a first temperature of the memory cell.

15. The method according to claim 14, wherein modulating the bit line comprises increasing an initial clamp voltage to the bit line to be different from an initial clamp voltage that is used to program verify or read the at least one memory cell at the first temperature and by increasing a final clamp voltage to the bit line to be different from than a final clamp voltage that is used to program verify or read the at least one memory cell at the first temperature.

16. The method according to claim 15, wherein initial clamp voltage used during the program verify or read operation is about 200 mV different from the initial clamp voltage used to program verify or read the at least one memory cell at the first temperature and the final clamp voltage is about 200 mV different from the final clamp voltage used to program verify or read the at least one memory cell at the first temperature.

17. The method according to claim 14, wherein the one or more memory cells comprises one or more NAND-type string devices.

18. The method according to claim 14, wherein the one or more memory cells comprises one or more non-volatile memory cells.

19. The method according to claim 14, wherein the memory device comprises part of a solid-state drive (SSD).

20. The method according to claim 14, wherein the memory device comprises part of an array of memory devices.
